(19) United States
(12) Patent Application Publication
(10) Pub. No.: US 2012/0208312 A1
(43) Pub. Date: Aug. 16, 2012

(54) METHOD OF MANUFACTURING ORGANIC PHOTOVOLTAIC DEVICE

(76) Inventors: Nikhil Agrawal, New Delhi (IN); Gopalan Rajeswaran, New Delhi (IN); Rajeev Jindal, New Delhi (IN)

(21) Appl. No.: 13/100,843

(22) Filed: May 4, 2011

(30) Foreign Application Priority Data
May 6, 2010 (IN) 1063/DEL/2010

(51) Int. Cl. H01L 51/48

(52) U.S. Cl. 438/61; 257/E51.012

(57) ABSTRACT

A method of manufacturing an organic photovoltaic device of a pre-defined shape and size is provided. The method includes providing a first substrate with said pre-defined shape and size, the size being less than 900 square centimeters and depositing an organic photoactive layer on said first substrate followed by depositing an electrically conducting layer on said organic photoactive layer. Thereafter, said electrically conducting layer and said organic photoactive layer are scribed from said first substrate forming zones on first substrates, whereby forming an active substrate. Further, providing a second substrate with said pre-defined shape and size and depositing a gas-absorbent layer on said second substrate whereby forming an inactive substrate. Finally, encapsulating said active substrate with said inactive substrate to form said organic photovoltaic device with said pre-defined shape and size, whereby not involving cutting of said first substrate after deposition of said organic photoactive layer.

### FIELD OF INVENTION

The invention disclosed herein relates, in general, to a method of manufacturing organic photovoltaic devices. More specifically, the present invention relates to a method of mass manufacturing a low cost organic photovoltaic device.

### BACKGROUND

Presently, there are two processes for manufacturing an organic photovoltaic device. The first process is to manufacture a flexible organic photovoltaic device using a roll-to-roll manufacturing process. In the roll-to-roll manufacturing process flexible plastic foils are used as substrate to manufacture the organic photovoltaic devices. In the subsequent steps of the manufacturing process these plastic foils or rolls are cut into several small pieces to meet specific requirements. Organic photovoltaic devices manufactured from these flexible substrates have disadvantage of having a lower product life. The second process for manufacturing an organic photovoltaic device is to manufacture a non-flexible organic photovoltaic device using various coating processes such as slot dye coating, screen printing, etc on large non-flexible substrates. In the subsequent manufacturing steps the large substrates are sliced or cut to achieve specific requirements.

Thus, both the above methods involve depositing layers on a large area substrate, and then slicing or cutting the substrate to get smaller device sizes. This causes loss of product, thus lowering yield and eventually leading to higher product costs. Further, in one or more of the above processes, it is difficult to manufacture devices of customized shapes and sizes.

Therefore, there is a need for a low-cost, high-yield mass manufacturing method for manufacturing an organic photovoltaic device, by eliminating cutting or slicing of the substrate. The method should also enable manufacturing devices of customized shapes and sizes. Further, the manufacturing method could be used for manufacturing flexible or rigid organic photovoltaic devices.

### BRIEF DESCRIPTION OF FIGURES

The features of the present invention, which are believed to be novel, are set forth with particularity in the appended claims. The invention may best be understood by reference to the following description, taken in conjunction with the accompanying drawings. These drawings and the associated description are provided to illustrate some embodiments of the invention, and not to limit the scope of the invention.

FIG. 1 is a flow chart describing a method of manufacturing an organic photovoltaic device, in accordance with a first embodiment of the present invention;

FIG. 2 is a flow chart describing a method of manufacturing the organic photovoltaic device, in accordance with a second embodiment of the present invention;

FIG. 3 is a flow chart describing a method of manufacturing the organic photovoltaic device, in accordance with a third embodiment of the present invention;

FIG. 4 is a flow chart describing a method for encapsulating an active substrate with an inactive substrate, in accordance with an exemplary embodiment of the present invention;

FIGS. 5a and 5b are diagrammatic illustrations of a first substrate deposited with one or more layers, in accordance with at least the first, the second and the third embodiments of the present invention;

FIGS. 6a and 6b are diagrammatic illustrations of the first substrate and a second substrate deposited with corresponding one or more layers, in accordance with at least the first, the second and the third embodiments of the present invention;

FIG. 7 is a diagrammatic illustration of the active substrate, in accordance with at least the first embodiment of the present invention;

FIGS. 8a, 8b and 8c are diagrammatic illustrations of the active substrate at different steps of a method of manufacturing the organic photovoltaic device, in accordance with at least the third embodiment of the present invention;

FIG. 9 is a diagrammatic illustration of a real-life application of one or more organic photovoltaic devices connected with series or parallel connections, in accordance with another exemplary embodiment of the present invention; and

FIG. 10 is a diagrammatic illustration of one or more shapes of the first substrate, in accordance with another exemplary embodiment of the present invention.

Those with ordinary skill in the art will appreciate that the elements in the figures are illustrated for simplicity and clarity and are not necessarily drawn to scale. For example, the dimensions of some of the elements in the figures may be exaggerated, relative to other elements, in order to improve the understanding of the present invention.

There may be additional structures described in the foregoing application that are not depicted on one of the described drawings. In the event such a structure is described, but not depicted in a drawing, the absence of such a drawing should not be considered as an omission of such design from the specification.

### SUMMARY

The instant exemplary embodiments provide a method of manufacturing an organic photovoltaic device.

Some embodiments provide a manufacturing process for the organic photovoltaic device that increases yield and lowers the manufacturing cost of the organic photovoltaic device. This is achieved by reducing loss of product by eliminating any cutting or slicing of the device after deposition of layers. The organic photovoltaic devices produced using this process, are thus, substrate-sized devices. The process is suitable for substrates of a size less than 900 square centimeters. The organic photovoltaic devices formed of said substrates of a size less than 900 square centimeters can be combined to form bigger devices, without loss of product. Also, devices with customizable shapes can be achieved by combining the substrate sized products.

Some embodiments provide a method of mass manufacturing the organic photovoltaic device with increased yield.

Some embodiments provide a method of lowering the manufacturing cost of the organic photovoltaic device.

Some embodiments provide a method of manufacturing the organic photovoltaic device of customizable shapes.

Some embodiments provide a method of manufacturing the organic photovoltaic device, such that a capital investment for a manufacturing facility to implement the method is less.

Some embodiments provide a method of manufacturing the organic photovoltaic device that eliminates or reduces the limitations involved in manufacturing the organic photovoltaic device using a large substrate.

In some embodiments, a method is provided for manufacturing an organic photovoltaic device of a pre-defined shape and size. The method includes providing a first substrate of a pre-defined shape and size, the pre-defined size being less than 900 square centimeters, and depositing an organic photoactive layer on the first substrate. Thereafter, the method includes depositing an electrically conducting layer on the organic photoactive layer. Then, the method includes scribing of the electrically conducting layer and the organic photoactive layer from the first substrate forming zones of the electrically conducting layer and the organic photoactive layer on the first substrate. This forms an active substrate.

Additionally, a second substrate of pre-defined shape and size is provided and a gas-absorbent layer is deposited on the second substrate. This forms an inactive substrate.

The active substrate is then encapsulated with the inactive substrate to form the organic photovoltaic device of the pre-defined shape and size. Therefore, the method of manufacturing the organic photovoltaic device did not require cutting of the first substrate after deposition of the organic photoactive layer to achieve the pre-defined size.

In some embodiments, a method of manufacturing an organic photovoltaic device of pre-defined surface area is provided. The method includes providing a first substrate that has a surface area substantially equal to the pre-defined surface area, which is not greater than 900 square centimeters. The method further involves depositing one or more organic material layers on the first substrate by using either a batch deposition-process or an in-line process. Thereafter, a first high-throughput deposition-processing is performed on said one or more organic material layers, such that the first high-throughput deposition-processing is substantially suitable for the pre-defined surface area.

Additionally, a second substrate of a surface area substantially equal to and not greater than the pre-defined surface area is provided, and a second high-throughput deposition-processing is performed on it. The second high-throughput deposition-processing is also substantially suitable for the pre-defined surface area.

The first substrate is then encapsulated or bonded with the second substrate to form the organic photovoltaic device. The organic photovoltaic device is capable of generating electricity without a subsequent cutting process.

In some embodiments, the method of manufacturing the organic photovoltaic device having a pre-defined surface area includes providing a first substrate that has a surface area substantially equal to the pre-defined surface area, which is not greater than 900 square centimeters. Then a high-throughput depositing of a hole-transport layer is performed on the first substrate, such that the high-throughput depositing of the hole-transport layer is suitable for the pre-defined surface area. Thereafter, a first organic photoactive layer is deposited on the hole-transport layer by using either a batch deposition-process or an in-line process.

Optionally, the method may include high-throughput depositing of a first electrically conducting layer on the first organic photoactive layer, such that the optional high-throughput depositing of the first electrically conducting layer is suitable for the pre-defined surface area. Further, the method may also include optionally depositing a second organic photoactive layer on the first electrically conducting layer such that the second organic photoactive layer is deposited by using a batch deposition-process or an in-line process.

Then, the method includes high-throughput scribing of the second organic photoactive layer, the first electrically conducting layer, the first organic photoactive layer and the hole-transport layer from the first substrate, followed by high-throughput depositing of a second electrically conducting layer, such that, the high-throughput depositing is suitable for the pre-defined surface area. Thereafter, the second electrically conducting layer is scribed using high-throughput scribing, thereby forming an active substrate.

Additionally, a second substrate of a surface area substantially equal to and not greater than the pre-defined surface area is provided, and a high-throughput depositing of a gas-absorbent layer is performed on it to form an inactive substrate. The high-throughput depositing of the gas-absorbent layer is also suitable for the pre-defined surface area.

Thereafter, the active substrate is encapsulated or bonded with the inactive substrate to form the organic photovoltaic device. The organic photovoltaic device is capable of generating electricity without a subsequent cutting process.

In some embodiments, each layer from the hole-transport layer, the first organic photoactive layer, the first electrically conducting layer, the second organic photoactive layer, the second electrically conducting layer and the gas-absorbent layer is deposited by using a high-throughput manufacturing process that is suitable for the pre-defined size, i.e., a small form factor. Some examples of the high-throughput manufacturing process include, but are not limited to, dip coating, spin coating, doctor blade processing, spray coating, screen printing, sputtering, electroforming, evaporation and an in-line process.

### DESCRIPTION OF THE EXEMPLARY EMBODIMENTS

Before describing the present invention in detail, it should be observed that the present invention utilizes a combination of method steps and apparatus components related to a method of manufacturing an organic solar cell. Accordingly the apparatus components and the method steps have been represented where appropriate by conventional symbols in the drawings, showing only specific details that are pertinent for an understanding of the present invention so as not to obscure the disclosure with details that will be readily apparent to those with ordinary skill in the art having the benefit of the description herein.

While the specification concludes with the claims defining the features of the invention that are regarded as novel, it is believed that the invention will be better understood from a consideration of the following description in conjunction with the drawings, in which like reference numerals are carried forward.

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting but rather to provide an understandable description of the invention.

The terms “a” or “an”, as used herein, are defined as one or more than one. The term “another”, as used herein, is defined as at least a second or more. The terms “including” and/or “having” as used herein, are defined as comprising (i.e. open transition). The term “coupled” or “operatively coupled” as used herein, is defined as connected, although not necessarily directly, and not necessarily mechanically.

The present invention provides a manufacturing process for the organic photovoltaic device that increases yield and lowers the manufacturing cost of the organic photovoltaic device. This is achieved by reducing loss of product by eliminating any cutting or slicing of the device after deposition of layers. The organic photovoltaic devices produced using this process, are thus, substrate-sized devices. The process is suitable for substrates of a size less than 900 square centimeters. The organic photovoltaic devices formed of said substrates of a size less than 900 square centimeters can be combined to form bigger devices, without loss of product. Also, devices with customizable shapes can be achieved by combining the substrate sized products.

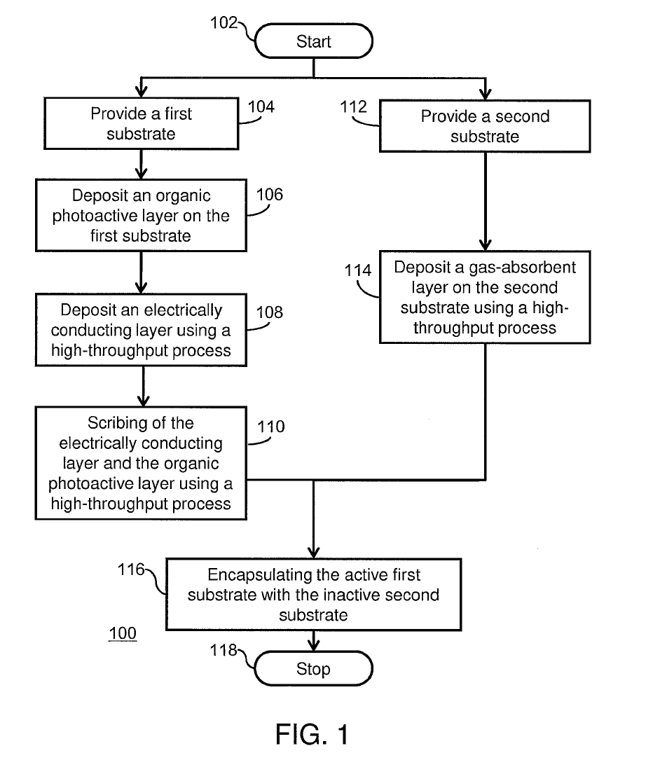

Referring now to the drawings, FIG. 1 is a flow chart describing a method 100 of manufacturing an organic photovoltaic device, in accordance with a first embodiment of the present invention. The organic photovoltaic device has a pre-defined shape and size.

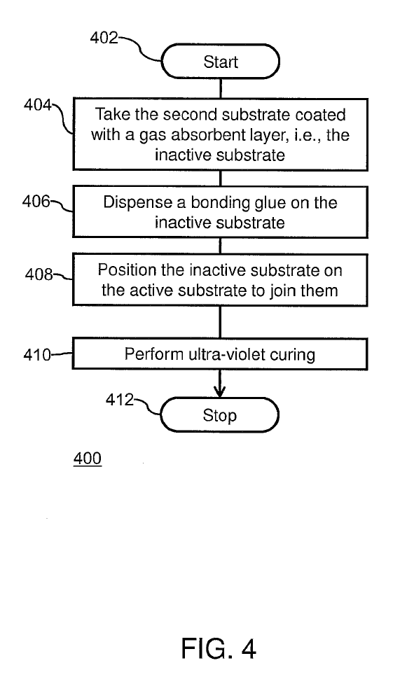

In the subsequent description of the method 100, reference will be made to FIGS. 4, 5a, 5b, 6a, 6b, 7 and 10 to elaborate on structural information pertaining to various embodiments of the organic photovoltaic device and the method 100.

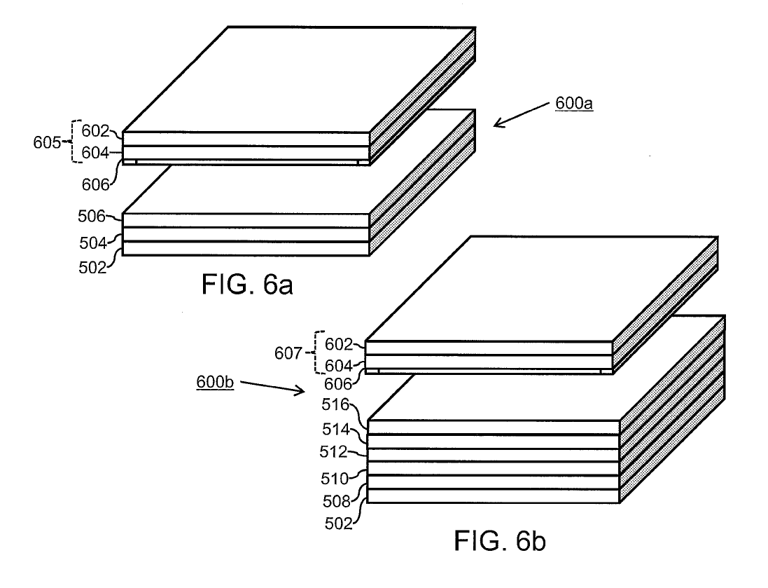

For the purpose of this description, the method 100 is explained for manufacturing of an organic photovoltaic device 600a (Refer FIG. 6a). However, it will be readily apparent to those ordinarily skilled in the art that the method 100 can be used for manufacturing of an organic photovoltaic device 600b (Refer FIG. 6b) or another organic photovoltaic device having the layers of the organic photovoltaic device 600a along with one or more additional layers.

The method 100 is initiated at step 102. At step 104, a first substrate 502 is provided. A shape and size of the first substrate 502 is substantially equal to the pre-defined shape and size, the pre-defined size is not greater than 900 square centimeters. The method 100 yields good results for substrates with size less than 900 square centimeters. In accordance with the invention the first substrate 502 does not require any cutting or slicing in the subsequent manufacturing steps of the organic photovoltaic device and substrate sized devices are manufactured. The first substrate 502 can be a square substrate of dimensions not greater than 30 cm×30 cm. The square substrate of dimensions substantially equal to and not greater than 30 cm×30 cm, is a standard-sized substrate, and significant number of manufacturing processes and equipments are standardized and optimized for a substrate of this size or surface area. For example, processes like, dip coating, spin coating, doctor blade processing, spray coating, screen printing, sputtering, electroforming and evaporation are already standardized for such a size and the corresponding manufacturing equipments are available as standard equipments.

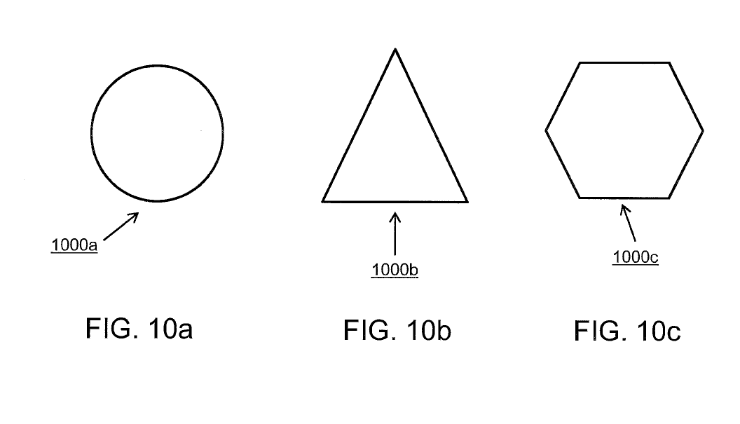

In accordance with this invention, the first substrate 502 can be of any shape and size as long as the size of the first substrate 502 is less than 900 square centimeters. For example, referring to FIG. 10, the first substrate 502 can be a circular substrate 1000a, a triangular substrate 1000b or a hexagonal substrate 1000c. Although, the shape of the first substrate 502 is shown as circular, triangular or hexagonal in FIG. 10, it will be readily apparent to those skilled in the art that the invention can be practiced with the first substrate 502 of a shape that can be, but is not limited to, polygonal, annular or elliptical.

In one embodiment, the first substrate 502 may include a glass substrate coated with an electrically conducting layer or an electrically conducting grid. Examples of the electrically conducting layer include, but are not limited to, a transparent conducting oxide (TCO), like, Indium Tin Oxide (ITO), Fluorine doped Tin Oxide (FTO), and Aluminum doped Zinc Oxide or a Carbon Nanotube Layer. Examples of the electrically conducting grid may include, but are not limited to, grids made from Aluminum, Copper, Gold, Silver, Polysilicon and a Silicide. In other embodiment, the first substrate 502 may include a transparent plastic substrate coated with an electrically conducting layer or an electrically conducting grid.

In an embodiment, the first substrate 502 is cleaned prior to performing subsequent steps of the method 100. For example, the first substrate 502 may be cleaned using an Ultrasonic or a Megasonic cleaning technique.

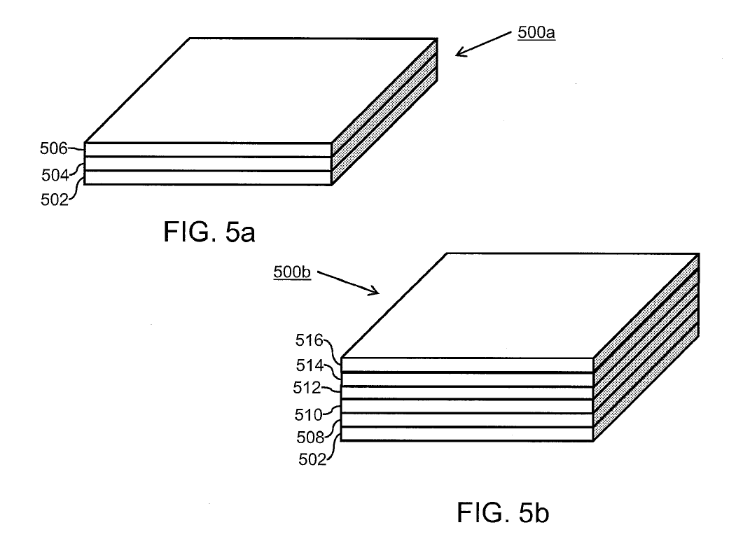

Thereafter, at step 106 an organic photoactive layer 504 (Refer FIG. 5a) is deposited on the first substrate 502. The organic photoactive layer 504 is responsible for generation of electricity in the organic photovoltaic device 600a. Photons present in the sun light received by the organic photoactive layer 504 generate excitons, i.e., bound electron-hole pairs, within the organic photoactive layer 504. These bound electron-hole pairs dissociate into free electrons and holes within the organic photoactive layer 504. The free electrons and holes act as the charge carriers that are responsible for generating electricity.

Examples of materials used for the organic photoactive layer 504, include, but are not limited to, polyphenylene vinylene, copper phthalocyanine, carbon fullerenes and fullerene derivatives such as Phenyl-C61-butyric acid methyl ester, i.e., PCBM.

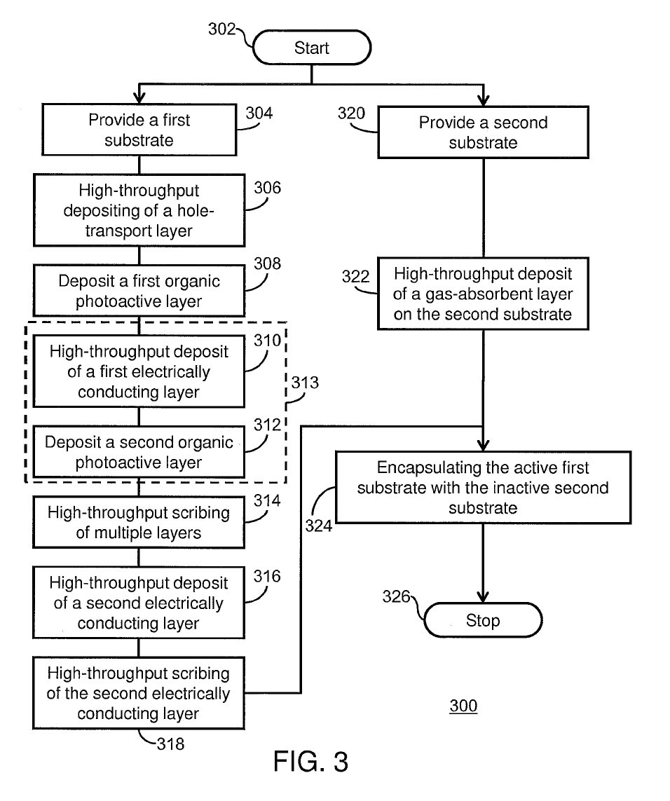

In another embodiment, the organic photovoltaic device 600a may also include a hole-transport layer. The hole-transport layer is deposited on the first substrate 502 prior to depositing the organic photoactive layer. The hole-transport layer is provided to enhance the transport of holes in the organic photovoltaic device 600a, thereby enhancing the efficiency of the organic photovoltaic device 600a. This embodiment is illustrated in conjunction with FIG. 3.

The organic photoactive layer 504 is deposited by using a batch deposition-process or an in-line process.

In the batch process for depositing the organic photoactive layer 504, for example, an input set of multiple first substrates is provided. The organic photoactive layer 504 is deposited on each first substrate 502 of the multiple first substrates. An output of the batch process is a set of multiple deposited first substrates, i.e., a set of the multiple first substrates deposited with the organic photoactive layer 504. Thereafter, the multiple deposited first substrates are carried forward for further processing as per subsequent steps of the method 100.

In an in-line process, for example, the first substrate 502 is received as an input, deposited with the organic photoactive layer 504, and a deposited first substrate is provided as an output. Thereafter, the deposited first substrate is carried forward for further processing as per the subsequent steps of the method 100, while another first substrate is received as an input.

Examples of processes that can be implemented as the batch-deposition process and the in-line process for the step 106 include, but are not limited to, dip coating, spin coating, doctor blade processing, spray coating, screen printing, sputtering, electroforming and evaporation.

It will be readily apparent to those ordinarily skilled in the art that either of the batch process and the in-line process may be included in the method 100 without deviating from the scope of the invention. It will also be readily apparent to those ordinarily skilled in the art that the method 100 may be optimized for high-throughput by using either the batch process or the in-line process.

At step 108, an electrically conducting layer 506 is deposited on the organic photoactive layer 504 using a high-throughput process.

The high-throughput deposition is performed using a manufacturing process which is suitable for the pre-defined size, i.e., the small form factor of substrates. Examples of the manufacturing process include, but are not limited to, dip coating, spin coating, doctor blade processing, spray coating, screen printing, sputtering, electroforming and evaporation.

Most of the high-throughput manufacturing process mentioned above have been optimized and standardized for the pre-defined size, i.e., for a surface area of substantially equal to but not greater than 900 square centimeters. However, there are limitations on using these processes for larger substrates, i.e., for substrates larger than the pre-defined size. They tend to generate outputs of sub-optimal quality or efficiency. For example, the uniformity of thickness of layers deposited by using spin coating may not be maintained over the large substrates. It may also induce defects, like, pinholes and non-homogeneity of the layers when used on large substrates.

Generally, a high-throughput manufacturing process is a process that is suitable for mass production, and therefore, produces a large quantity of products in a given time. In context of the method 100, when a method step is mentioned to have a high-throughput, for example, the step 108 of the high-throughput deposition of the electrically conducting layer 506, it refers that the method step is suitable to be performed for producing a bulk quantity of organic photovoltaic devices. Generally, the high-throughput process can be defined as a process capable of processing nearly 2.5 million products per year. In other words, the high-throughput process is a process that requires nearly 10 seconds for processing each product. Therefore, the high-throughput deposition of the electrically conducting layer 506 on the organic material layer 504 of the first substrate 502 is substantially performed in nearly 10 seconds. Thus, the high-throughput process increases the yield and lowers the manufacturing cost of the organic photovoltaic device.

Although, the high-throughput process is explained in reference to the high-throughput deposition of the electrically conducting layer 506 on the first substrate 502, it will be readily apparent to those ordinarily skilled in the art that another method step in the method 100 that is mentioned to be a high-throughput process may be substantially similar to the high-throughput process in context of producing nearly 2.5 million products per year and requiring nearly 10 seconds for processing each product.

It will also be appreciated by a person skilled in the art that a production capacity of 2.5 million products per year and a tact time of 10 seconds are provided only as an example for illustrating the high-throughput process, and do not depict any limitation of the invention. The production capacity and the tact time of the high-throughput process, in accordance with the present invention, may be higher or lower than the ranges mentioned above.

The electrically conducting layer 506 deposited on the organic photovoltaic layer 504 acts as one of the electrical contacts for connecting the organic photovoltaic device 600a to an external circuit requiring electricity or one or more organic photovoltaic devices. Generally, the electrically conducting layer 506 deposited on the organic photovoltaic layer 504 acts as a cathode. The electrically conducting layer or the electrically conducting grid deposited on the glass substrate, of the first substrate 502, acts as another electrical contact for connecting the organic photovoltaic device 600a to the external circuit requiring electricity or to the one or more organic photovoltaic devices. Generally, the electrically conducting layer or the electrically conducting grid deposited on the glass substrate, of the first substrate 502, acts as an anode.

Examples of the electrically conducting layer 506 include, but are not limited to, a transparent conducting oxide (TCO), like, Indium Tin Oxide (ITO), Fluorine doped Tin Oxide (FTO), and Aluminum doped Zinc Oxide or a Carbon Nanotube Layer.

Thereafter, at step 110, the organic photoactive layer 504 and the electrically conducting layer 506 are scribed from the first substrate 502 using a high-throughput method.

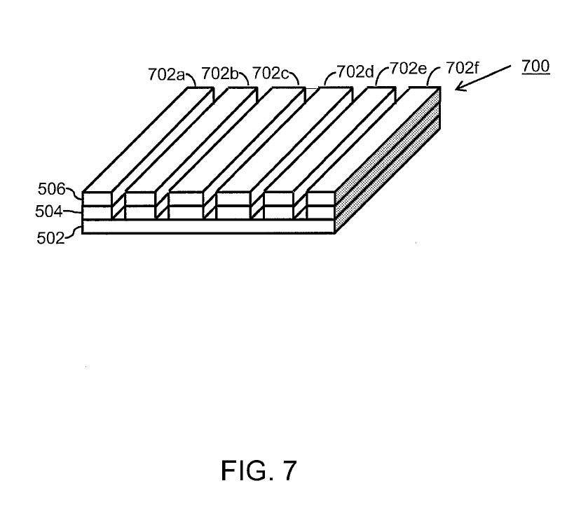

Referring to FIG. 7, the high-throughput scribing of the organic photoactive layer 504, the electrically conducting layer 506 forms zones 702a, 702b, 702c, 702d, 702e and 702f on the first substrate 502 and also connects the zones 702a, 702b, 702c, 702d, 702e and 702f in series to form an active substrate 700.

A zone voltage across the electrically conducting layer or the electrically conducting grid of the first substrate 502 and the electrically conducting layer 506 is substantially similar for the each zone. For example, in a hypothetical scenario, the zone voltage can be 0.7 volts. When the zones 702a, 702b, 702c, 702d, 702e and 702f are connected in series at the step 110 to form the active substrate 700, a combined voltage of the active substrate 700 is substantially equivalent to an addition of the zone voltages of all the zones 702a, 702b, 702c, 702d, 702e and 702f, i.e., 0.7×6=4.2 volts.

At step 112, a second substrate 602 (Refer FIG. 6a) of pre-defined shape and size is provided having a size substantially equal to and not greater than the pre-defined size of less than 900 square centimeters, i.e., the small form factor. The shape and size of the second substrate 602 is substantially similar and equal to the shape and size of the first substrate 502. Referring to FIG. 10, the second substrate can be a circular substrate 1000a, a triangular substrate 1000b or a hexagonal substrate 1000c. Although, the shape of the second substrate 602 is shown as circular, triangular or hexagonal in FIG. 10, it will be readily apparent to those skilled in the art that the invention can be practiced with the second substrate 602 of a shape that can be, but is not limited to, polygonal, annular or elliptical. Examples of the material of the second substrate 602 include, but are not limited to, glass.

In an embodiment, the second substrate 602 is cleaned prior to performing subsequent steps of the method 100. For example, the second substrate 602 may be cleaned using an Ultrasonic or a Megasonic cleaning technique.

At step 114, a gas-absorbent layer 604 is deposited on the second substrate 602 using a high-throughput process, thereby forming an inactive substrate 605. The high-throughput depositing of the gas-absorbent layer 604 is performed using a manufacturing process which is suitable for the pre-defined size, i.e., the small form factor of substrates. Examples of the manufacturing process include, but are not limited to, dip coating, spin coating, doctor blade processing, spray coating, screen printing, sputtering, electroforming and evaporation.

The gas-absorbent layer 604 is provided to absorb any gases that are released during the method 100 of manufacturing the organic photovoltaic device 600a and during a use of the organic photovoltaic device 600a. For example, the organic photovoltaic device 600a may undergo a curing process or exposure to heat and/or strong ultra-violet rays during the manufacturing in accordance with the method 100. This may result in release of contaminating gases from one or more layers in the organic photovoltaic device 600a. The gas-absorbent layer 604 prevents contamination of the organic photovoltaic device 600a from the contaminating gases.

At step 116, the first substrate 502, which is deposited with one or more layers 504 and 506 as per the foregoing steps of the method 100, is encapsulated or bonded with the second substrate 602, which is deposited with the gas-absorbent layer 604. In the subsequent description of the method 100, the first substrate 502, which is deposited with the one or more layers 504 and 506, is referred to as an active substrate 500a. Similarly, the second substrate 602, which is deposited with the gas-absorbent layer 604, is referred to as an inactive substrate 605.

The active substrate 500a is so termed as it includes the one or more organic material layers 504 capable of generating electricity. Similarly, the inactive substrate 605 is so termed as it does not include a layer capable of generating electricity.

A process of encapsulation is explained with reference to a method 400 depicted by a flow chart in FIG. 4. The method 400 initiates at step 402, the inactive substrate 605 is taken at step 404 and a bonding glue 606 is dispensed on the inactive substrate 605 at step 406. The bonding glue 606 is dispensed on a surface of the inactive substrate 605 that has the gas-absorbent layer 604. Thereafter, at step 408, the inactive substrate 605, dispensed with bonding glue 606 is positioned over the active substrate 500a. The gas-absorbent layer 604 may absorb any gases trapped between the active substrate 500a and the inactive substrate 605 during the step 406. Thereafter, at step 410, an exposure of ultra-violet radiation is provided to perform ultra-violet curing and complete the encapsulation of the active substrate 500a with the inactive substrate 605. The gas-absorbent layer 604 may absorb any gases released during the step 408. The encapsulation method terminates at step 412. Although, the method 400 is shown to include ultra-violet curing, it will be readily apparent to those ordinarily skilled in the art that other forms of curing may also be performed without deviating from the scope of the invention.

Thereafter, the method 100 of manufacturing the organic photovoltaic device 600a also terminates at step 118.

As per the foregoing description of steps involved in the method 100, the method 100 does not involve a cutting process. Absence of the cutting process makes the method 100 efficient. Additionally, since the cutting process is not involved, a size of the organic photovoltaic device 600a is substantially similar to a size of the first substrate 502 and/or the second substrate 602, i.e., an input substrate is similar in size to an output device.

Each of the steps involved in the method 100 may be performed by either a batch process or an inline process. Further, the each of the steps involved in the method 100 may be implemented in such a way that a tact time of the manufacturing facility used to implement the method 100 is optimum. In an exemplary scenario, a time corresponding to each of the method steps in method 100 is designed to be substantially same, thereby reducing a waiting time between each process and optimizing the tact time for the manufacturing facility.

In real life applications, one or more organic photovoltaic devices manufactured as per the method 100 may be connected by using series or parallel connections to obtain an arrangement that can produce electrical output as per a requirement. Additionally, the one or more organic photovoltaic devices may be connected by using series or parallel connections to obtain an optimum electrical output.

In an exemplary real life scenario, an electrical equipment with a voltage requirement of 42 volts needs to be run using solar energy. Further, in this exemplary scenario, the voltage output of the organic photovoltaic device can be 4.2 volts (0.7 volts per zone X 6 zones, 702a, 702b, 702c, 702d, 702e and 702f). Therefore, 10 such organic photovoltaic devices can be connected in series to obtain the required output of 42 volts and run the electrical equipment with solar energy.

In accordance with the invention photovoltaic devices can be manufactured with substrates of size less than 900 square centimeters and any desired shape to obtain substrate sized photovoltaic devices. The manufactured substrate sized photovoltaic devices with size less than 900 square centimeters and different shapes can be connected to form larger devices of any desired shape and size. For example, a hexagonal shaped photovoltaic device of a larger size can be obtained by connecting multiple square and triangular shaped photovoltaic devices of small size. This process of obtaining a large sized photovoltaic device of any desired shape by combining photovoltaic devices of different shapes and sizes does not involve any loss of product due to cutting or slicing of the device after deposition of layers. Thus, customized shapes can be achieved in large sized photovoltaic devices without involving any loss of product. It will be readily apparent to those ordinarily skilled in the art that the one or more organic photovoltaic devices may also be connected with photovoltaic devices prepared from other methods in real life applications.

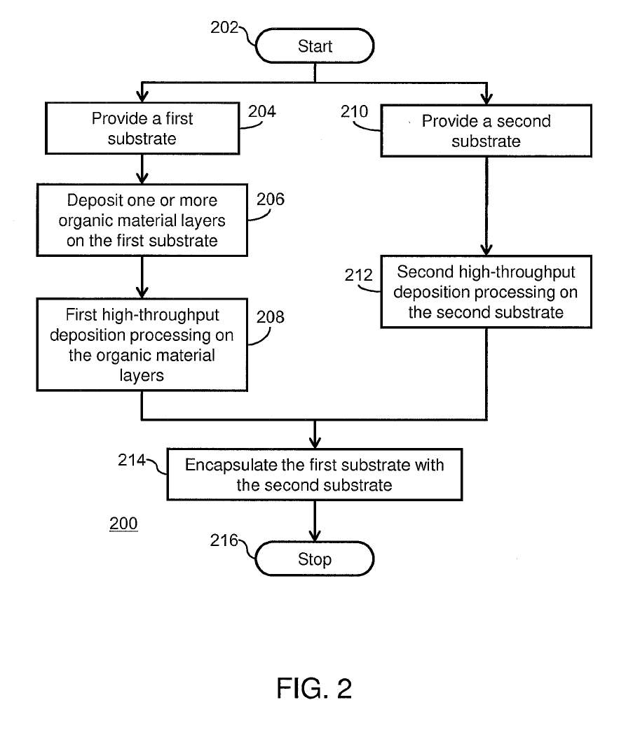

Referring now to the drawings, FIG. 2 is a flow chart describing a method 200 of manufacturing an organic photovoltaic device, in accordance with the second embodiment of the present invention. The organic photovoltaic device has a pre-defined surface area.

In the subsequent description of the method 200, reference will be made to FIGS. 4, 5a, 5b, 6a and 6b to elaborate on structural information pertaining to various embodiments of the organic photovoltaic device and the method 200.

For the purpose of this description, the method 200 is explained for manufacturing of an organic photovoltaic device 600a (Refer FIG. 6a). However, it will be readily apparent to those ordinarily skilled in the art that the method 200 can be used for manufacturing of an organic photovoltaic device 600b (Refer FIG. 6b) or another organic photovoltaic device having the layers of the organic photovoltaic device 600a along with one or more additional layers.

The method 200 is initiated at step 202. At step 204, a first substrate 502 is provided. A surface area of the first substrate 502 is substantially equal to the pre-defined surface area, which is not greater than 900 square centimeters. For example, the first substrate 502 can be a square substrate of dimensions not greater than 30 cm×30 cm. The square substrate of dimensions substantially equal to and not greater than 30 cm×30 cm, is a standard-sized substrate, and significant number of manufacturing processes and equipments are standardized and optimized for a substrate of this size or surface area. For example, processes like, dip coating, spin coating, doctor blade processing, spray coating, screen printing, sputtering, electroforming and evaporation are already standardized for such a size and the corresponding manufacturing equipments are available as standard equipments.

In accordance with this invention, the first substrate 502 can be of any shape as long as the surface area of the first substrate 502 is substantially equal to but not greater than 900 square centimeters. For example, in one embodiment the first substrate 502 can be circular in shape, however, in another embodiment, the shape of the first substrate 502 can be, but is not limited to, polygonal, annular or elliptical.

In one embodiment, the first substrate 502 may include a glass substrate coated with an electrically conducting layer or an electrically conducting grid. Examples of the electrically conducting layer include, but are not limited to, a transparent conducting oxide (TCO), like, Indium Tin Oxide (ITO), Fluorine doped Tin Oxide (FTO), and Aluminum doped Zinc Oxide or a Carbon Nanotube Layer. Examples of the electrically conducting grid may include, but are not limited to, grids made from Aluminum, Copper, Gold, Silver, Polysilicon and a Silicide. In other embodiment, the first substrate 502 may include a transparent plastic substrate coated with an electrically conducting layer or an electrically conducting grid.

In an embodiment, the first substrate 502 is cleaned prior to performing subsequent steps of the method 200. For example, the first substrate 502 may be cleaned using an Ultrasonic or a Megasonic cleaning technique.

Thereafter, at step 206 one or more organic material layers 504 (Refer FIG. 5a) are deposited on the first substrate 502. In one embodiment, the one or more organic material layers 504 include an organic photoactive layer 510 (Refer FIG. 5b) that is responsible for generation of electricity in the organic photovoltaic device 600a. Photons present in the sun light received by the organic photoactive layer 510 generate excitons, i.e., bound electron-hole pairs, within the organic photoactive layer 510. These bound electron-hole pairs dissociate into free electrons and holes within the organic photoactive layer 510. The free electrons and holes act as the charge carriers that are responsible for generating electricity.

Examples of materials used for the organic photoactive layer 510, include, but are not limited to, polyphenylene vinylene, copper phthalocyanine, carbon fullerenes and fullerene derivatives such as Phenyl-C61-butyric acid methyl ester, i.e., PCBM.

In another embodiment, the one or more organic material layers 504 may also include a hole-transport layer 508 (Refer FIG. 5b) in addition to the organic photoactive layer 510. The hole-transport layer 508 is deposited prior to depositing the organic photoactive layer 510. The hole-transport layer 508 is provided to enhance the transport of holes in the organic photovoltaic device 600a, thereby enhancing the efficiency of the organic photovoltaic device 600a.

Each of said one or more organic material layers, i.e., the hole-transport layer 508 and the organic photoactive layer 510 is deposited by using a batch deposition-process or an in-line process.

In the batch process for depositing the organic photoactive layer 510, for example, an input set of multiple first substrates is provided. The organic photoactive layer 510 is deposited on each first substrate 502 of the multiple first substrates. An output of the batch process is a set of multiple deposited first substrates, i.e., a set of the multiple first substrates deposited with the organic photoactive layer 510. Thereafter, the multiple deposited first substrates are carried forward for further processing as per subsequent steps of the method 200.

In an in-line process, for example, the first substrate 502 is received as an input, deposited with the organic photoactive layer 510, and a deposited first substrate is provided as an output. Thereafter, the deposited first substrate is carried forward for further processing as per the subsequent steps of the method 200, while another first substrate is received as an input.

Examples of processes that can be implemented as the batch-deposition process and the in-line process for the step 206 include, but are not limited to, dip coating, spin coating, doctor blade processing, spray coating, screen printing, sputtering, electroforming and evaporation.

It will be readily apparent to those ordinarily skilled in the art that either of the batch process and the in-line process may be included in the method 200 without deviating from the scope of the invention. It will also be readily apparent to those ordinarily skilled in the art that the method 200 may be optimized for high-throughput by using either the batch process or the in-line process.

At step 208, a first high-throughput deposition-processing is performed on the one or more organic material layers 504. Referring to FIG. 5b, irrespective of a presence of the hole-transport layer 508, the first high-throughput deposition-processing is performed on the organic photoactive layer 510.

The first high-throughput deposition-processing is performed using a manufacturing process which is suitable for the pre-defined surface area, i.e., the small form factor of substrates. Examples of the manufacturing process include, but are not limited to, dip coating, spin coating, doctor blade processing, spray coating, screen printing, sputtering, electroforming and evaporation.

Most of the high-throughput manufacturing process mentioned above have been optimized and standardized for the pre-defined size, i.e., for a surface area of substantially equal to but not greater than 900 square centimeters. However, there are limitations on using these processes for larger substrates, i.e., for substrates larger than the pre-defined size. They tend to generate outputs of sub-optimal quality or efficiency. For example, the uniformity of thickness of layers deposited by using spin coating may not be maintained over the large substrates. It may also induce defects, like, pinholes and non-homogeneity of the layers when used on large substrates.

Generally, a high-throughput manufacturing process is a process that is suitable for mass production, and therefore, produces a large quantity of products in a given time similar to the high-throughput manufacturing process explained in conjunction with the method 100.

In an embodiment, the first high-throughput deposition-processing may include depositing an electrically conducting layer 506 (Refer FIG. 5a) on the one or more organic material layers 504. In the embodiment when the one or more organic material layers 504 include only the organic photoactive layer 510, the electrically conducting layer 506 is deposited on the organic photoactive layer 510. Similarly, in the embodiment when the one or more organic material layers 504 include the hole-transport layer 508 and the organic photoactive layer 510, the electrically conducting layer 506 is deposited on the organic photoactive layer 510.

The electrically conducting layer 506 deposited on the organic photovoltaic layer 510 acts as one of the electrical contacts for connecting the organic photovoltaic device 600a to an external circuit requiring electricity or one or more organic photovoltaic devices. Generally, the electrically conducting layer 506 deposited on the organic photovoltaic layer 510 acts as a cathode. The electrically conducting layer or the electrically conducting grid deposited on the glass substrate, of the first substrate 502, acts as another electrical contact for connecting the organic photovoltaic device 600a to the external circuit requiring electricity or to the one or more organic photovoltaic devices. Generally, the electrically conducting layer or the electrically conducting grid deposited on the glass substrate, of the first substrate 502, acts as an anode.

Examples of the electrically conducting layer 506 include, but are not limited to, a transparent conducting oxide (TCO), like, Indium Tin Oxide (ITO), Fluorine doped Tin Oxide (FTO), and Aluminum doped Zinc Oxide or a Carbon Nanotube Layer.

At step 210, a second substrate 602 (Refer FIG. 6a) is provided having a surface area substantially equal to and not greater than the pre-defined surface area of less than 900 square centimeters, i.e., the small form factor. Examples of the material of the second substrate 602 include, but are not limited to, glass.

In an embodiment, the second substrate 602 is cleaned prior to performing subsequent steps of the method 200. For example, the second substrate 602 may be cleaned using an Ultrasonic or a Megasonic cleaning technique.

At step 212, a second high-throughput deposition-processing is performed on the second substrate 602. The second high-throughput deposition-processing is performed using a manufacturing process which is suitable for the pre-defined surface area, i.e., the small form factor of substrates. Examples of the manufacturing process include, but are not limited to, dip coating, spin coating, doctor blade processing, spray coating, screen printing, sputtering, electroforming and evaporation.

The second high-throughput deposition-processing may include high-throughput deposition a gas-absorbent layer 604 (Refer FIG. 6a). The gas-absorbent layer 604 is provided to absorb any gases that are released during the method 200 of manufacturing the organic photovoltaic device 600a and during a use of the organic photovoltaic device 600a. For example, the organic photovoltaic device 600a may undergo a curing process or exposure to heat and/or strong ultra-violet rays during the manufacturing in accordance with the method 200 (Refer description of step 214). This may result in a release of contaminating gases from one or more layers in the organic photovoltaic device 600a. The gas-absorbent layer 604 prevents contamination of the organic photovoltaic device 600a from the contaminating gases.

At step 214, the first substrate 502, which is deposited with one or more layers 504 and 506 as per the foregoing steps of the method 200, is encapsulated or bonded with the second substrate 602, which is deposited with the gas-absorbent layer 604. In the subsequent description of the method 200, the first substrate 502, which is deposited with the one or more layers 504 and 506, is referred to as an active substrate 500a. Similarly, the second substrate 602, which is deposited with the gas-absorbent layer 604, is referred to as an inactive substrate 605.

The active substrate 500a is so termed as it includes the one or more organic material layers 504 capable of generating electricity. Similarly, the inactive substrate 605 is so termed as it does not include a layer capable of generating electricity.

The method of encapsulation is similar to the method 400 explained with reference to FIG. 4 in conjunction with the foregoing description of method 100. Thereafter, the method 200 of manufacturing the organic photovoltaic device 600a also terminates at step 216.

As per the foregoing description of steps involved in the method 200, the method 200 does not involve a cutting process. Absence of the cutting process makes the method 200 efficient. Additionally, since the cutting process is not involved, a size of the organic photovoltaic device 600a is substantially similar to a size of the first substrate 502 and/or the second substrate 602, i.e., an input substrate is similar in size to an output device.

Each of the steps involved in the method 200 may be performed by either a batch process or an inline process. Further, the each of the steps involved in the method 200 may be implemented in such a way that a tact time of the manufacturing facility used to implement the method 200 is optimum. In an exemplary scenario, a time corresponding to each of the method steps in method 200 is designed to be substantially same, thereby reducing a waiting time between each process and optimizing the tact time for the manufacturing facility.

Referring now to FIG. 3, there is shown a flow chart describing a method 300 of manufacturing an organic photovoltaic device 600b (Refer FIG. 6), in accordance with the third embodiment of the present invention. The organic photovoltaic device 600b has the pre-defined surface area, which is not greater than 900 square centimeters.

In the subsequent description of the method 300, reference will be made to FIGS. 4, 5a, 5b, 6a, 6b, 8a, 8b, 8c and 9 to elaborate on structural information pertaining to various embodiments of the organic photovoltaic device 600b and the method 300.

For the purpose of this description, the method 300 is explained for manufacturing of the organic photovoltaic device 600b (Refer FIG. 6b). However, it will be readily apparent to those ordinarily skilled in the art that the method 300 can be used for manufacturing another organic photovoltaic device having the layers of the organic photovoltaic device 600b along with one or more additional layers.

The method 300 is initiated at step 302. At step 304, the first substrate 502 (Refer FIG. 5b) is provided. A surface area of the first substrate 502 is substantially equal to the pre-defined surface area, which is not greater than 900 square centimeters. For example, the first substrate 502 can be a square substrate of dimensions not greater than 30 cm×30 cm.

The first substrate 502 includes a glass substrate coated with an electrically conducting layer or an electrically conducting grid. Examples of the electrically conducting layer include, but are not limited to, a transparent conducting oxide (TCO), like, Indium Tin Oxide (ITO), Fluorine doped Tin Oxide (FTO), and Aluminum doped Zinc Oxide or a Carbon Nanotube Layer. Examples of the electrically conducting grid may include, but are not limited to, grids made from Aluminum, Copper, Gold, Silver, Polysilicon and a Silicide.

In an embodiment, the first substrate 502 is cleaned prior to performing subsequent steps of the method 300. For example, the first substrate 502 may be cleaned by using an Ultrasonic or a Megasonic cleaning technique.

Thereafter, at step 306 a high-throughput depositing of the hole-transport layer 508 is performed on the first substrate 502. The high-throughput depositing of the hole-transport layer 508 is performed using a manufacturing process which is suitable for the pre-defined surface area, i.e., the small form factor of substrates. Examples of the manufacturing process include, but are not limited to, dip coating, spin coating, doctor blade processing, spray coating, screen printing, sputtering, electroforming and evaporation.

Generally, a high-throughput manufacturing process is a process that is suitable for mass production, and therefore, produces a large quantity of products in a given time similar to the high-throughput manufacturing process explained in conjunction with the method 100.

The hole-transport layer 508 is provided to enhance the transport of holes in the organic photovoltaic device 600b, thereby enhancing the efficiency of the organic photovoltaic device 600b.

Thereafter, at step 308, a first organic photoactive layer 510 is deposited on the hole-transport layer 508. The first organic photoactive layer 510 is responsible for generation of electricity in the organic photovoltaic device 600b. Photons present in the sun light received by the first organic photoactive layer 510 generate excitons, i.e., bound electron-hole pairs, within the first organic photoactive layer 510. These bound electron-hole pairs dissociate into free electrons and holes within the first organic photoactive layer 510. The free electrons and holes act as the charge carriers that are responsible for generating electricity.

Examples of the materials used for the first organic photoactive layer 510, include, but are not limited to, polyphenylene vinylene, copper phthalocyanine, carbon fullerenes and fullerene derivatives such as Phenyl-C61-butyric acid methyl ester, i.e., PCBM.

The first organic photoactive layer 510 is deposited by using a batch deposition-process or an in-line process.

In the batch process for depositing the first organic photoactive layer 510, for example, an input set of multiple first substrates is provided. The first organic photoactive layer 510 is deposited on each first substrate 502 of the multiple first substrates. An output of the batch process is a set of multiple deposited first substrates, i.e., a set of the multiple first substrates deposited with the first organic photoactive layer 510. Thereafter, the multiple deposited first substrates are carried forward for further processing as per subsequent steps of the method 300.

In an in-line process, for example, the first substrate 502 is received as an input, deposited with the first organic photoactive layer 510, and a deposited first substrate is provided as an output. Thereafter, the deposited first substrate is carried forward for further processing as per the subsequent steps of the method 300, while another first substrate is received as an input.

Examples of processes that can be implemented as the batch-deposition process and the in-line process for the step 308 include, but are not limited to, dip coating, spin coating, doctor blade processing, spray coating, screen printing, sputtering, electroforming and evaporation.

It will be readily apparent to those ordinarily skilled in the art that either of the batch process and the in-line process may be included in the method 300 without deviating from the scope of the invention. It will also be readily apparent to those ordinarily skilled in the art that the method 300 may be optimized for high-throughput by using either the batch process or the in-line process.

Thereafter at step 310, an optional high-throughput depositing of a first electrically conducting layer 512 on said first organic photoactive layer 510 is performed. The first electrically conducting layer 512 is performed using a manufacturing process which is suitable for the pre-defined surface area, i.e., the small form factor of substrates. Examples of the manufacturing process include, but are not limited to, dip coating, spin coating, doctor blade processing, spray coating, screen printing, sputtering, electroforming and evaporation.

Thereafter, at step 312, a second organic photoactive layer 514 is optionally deposited on the first electrically conducting layer 512. The second organic photoactive layer 514 is also capable of converting solar energy in the form of light into electricity.

Further, the second organic photoactive layer 514 is also deposited by using a batch deposition-process or an in-line process.

As mentioned above and as depicted by the dashed box 313 in the method 300, the step 310 and the step 312 are optional. It will be readily apparent to those ordinarily skilled in the art that an organic photoactive device can be manufactured by omitting the step 310 and the step 312 from the method 300 without deviating from the scope of the present invention.

Performing the step 310 and the step 312 may have additional benefits as explained in conjunction with step 318.

For the purpose of this description, the subsequent steps of the method 300 are explained considering the presence of the step 310, the step 312 and the corresponding layers, i.e., the first electrically conducting layer 512 and the second organic photoactive layer 514.

Thereafter, at step 314, the second organic photoactive layer 514, the first electrically conducting layer 512, the first organic photoactive layer 510 and the hole-transport layer 508 are scribed from the first substrate 502 using a high-throughput method.

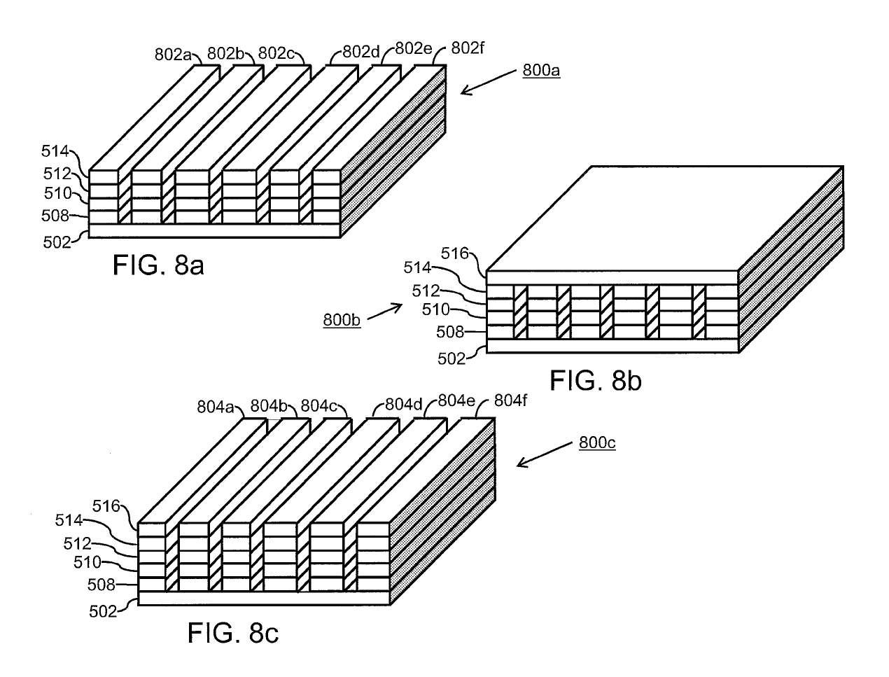

Referring to FIG. 8a, the high-throughput scribing of the second organic photoactive layer 514, the first electrically conducting layer 512, the first organic photoactive layer 510 and the hole-transport layer 508 forms zones 802a, 802b, 802c, 802d, 802e and 802f on the first substrate 502.

Thereafter, at step 316, a high-throughput depositing of a second electrically conducting layer 516 is performed on the scribed second organic photoactive layer 514 by using a manufacturing process which is suitable for the pre-defined surface area, i.e., the small form factor of substrates (Refer FIG. 8b). Examples of the manufacturing process include, but are not limited to, dip coating, spin coating, doctor blade processing, spray coating, screen printing, sputtering, electroforming and evaporation.

Thereafter, at step 318, the second electrically conducting layer 516 is scribed from the first substrate 502 using another high-throughput method, thereby forming an active substrate 800c (Refer FIG. 8c).

Referring to FIG. 8c, the high-throughput scribing of the second electrically conducting layer 516 forms zones 804a, 804b, 804c, 804d, 804e and 804f on the first substrate 502 and also connects the zones 804a, 804b, 804c, 804d, 804e and 804f in series, to form the active substrate 800c.

Each zone of the zones 804a, 804b, 804c, 804d, 804e and 804f has all the layers deposited on the first substrate 502, therefore, the each zone can act as two power-generating portions connected in series. A first power-generating portion formed between the electrically conducting layer or the electrically conducting grid deposited on the first substrate 502 and the first electrically conducting layer 512. A second power-generating portion formed between the first electrically conducting layer 512 and the second electrically conducting layer 516. The first power-generating portion and the second power-generating portion connected in series due to a common electrically conducting layer, i.e., the first electrically conducting layer 512. As a result, presence of the step 310 and the step 312 in the method 300 may help in increasing an efficiency and an electrical output of the organic photovoltaic device 600b by increasing a number of the power generating portions.

A zone voltage across the electrically conducting layer or the electrically conducting grid of the first substrate 502 and the second electrically conducting layer 516 is substantially similar for the each zone. For example, in a hypothetical scenario, the zone voltage can be 0.7 volts. When the zones 804a, 804b, 804c, 804d, 804e and 804f are connected in series at the step 318 to form the active substrate 800c, a combined voltage of the active substrate 800c is substantially equivalent to an addition of the zone voltages of all the zones 804a, 804b, 804c, 804d, 804e and 804f, i.e., 0.7×6=4.2 volts.

At step 320, a second substrate 602 is provided having a surface area substantially equal to and not greater than the pre-defined surface area of less than 900 square centimeters, i.e., the small form factor. Examples of the material of the second substrate include, but are not limited to, glass.

In an embodiment, the second substrate 602 is cleaned prior to performing subsequent steps of the method 300. For example, the second substrate 602 may be cleaned using an Ultrasonic or a Megasonic cleaning technique.

At step 322, a high-throughput depositing of a gas-absorbent layer 604 is performed on the second substrate 602, thereby forming an inactive substrate 607. The high-throughput depositing of the gas-absorbent layer 604 is performed using a manufacturing process which is suitable for the pre-defined surface area, i.e., the small form factor of substrates. Examples of the manufacturing process include, but are not limited to, dip coating, spin coating, doctor blade processing, spray coating, screen printing, sputtering, electroforming and evaporation.

The gas-absorbent layer 604 is provided to absorb any gases that are released during the method 300 of manufacturing the organic photovoltaic device 600b and during a use of the organic photovoltaic device 600b. For example, the organic photovoltaic device 600b may undergo a curing process or exposure to heat and/or strong ultra-violet rays during the manufacturing in accordance with the method 300. This may result in release of contaminating gases from one or more layers in the organic photovoltaic device 600b. The gas-absorbent layer 604 prevents contamination of the organic photovoltaic device 600b from the contaminating gases.

At step 324, the active substrate 800c is encapsulated or bonded with the inactive substrate 607. The method of encapsulation is similar to the method 400 explained with reference to FIG. 4 in conjunction with the foregoing description of FIG. 1.

Thereafter, the method 300 of manufacturing the organic photovoltaic device 600b terminates at step 326.

As per the foregoing description of steps involved in the method 100, the method 100 does not involve a cutting process. Absence of the cutting process makes the method 100 efficient. Additionally, since the cutting process is not involved, a size of the organic photovoltaic device 600b is substantially similar to a size of the first substrate 502 and/or the second substrate 602, i.e., an input substrate is similar in size to an output device.

Each of the steps involved in the method 300 may be performed by either a batch process or an inline process. Further, the each of the steps involved in the method 300 may be implemented in such a way that a tact time of the manufacturing facility used to implement the method 300 is optimum. In an exemplary scenario, a time corresponding to each of the method steps in method 300 is designed to be substantially same, thereby reducing a waiting time between each process and optimizing the tact time for the manufacturing facility.

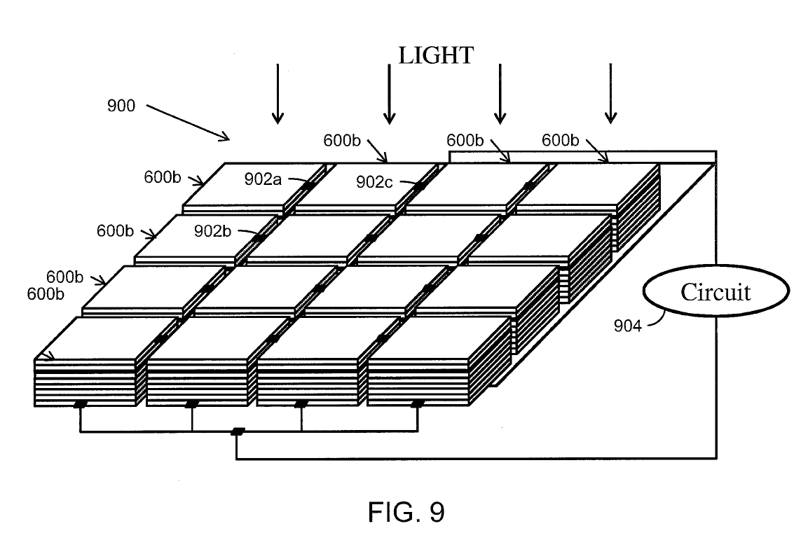

Referring to FIG. 9, one or more organic photovoltaic devices 600b manufactured as per the method 300 may be connected by using series or parallel connections 902a, 902b and 902c to obtain an arrangement 900 that can produce an electrical output as per a requirement, for example, the requirement of an external circuit 904. Additionally, one or more organic photovoltaic devices 600b may be connected by using series or parallel connections 902a, 902b and 902c to obtain an optimum electrical output.

It will be readily apparent to those ordinarily skilled in the art that the one or more organic photovoltaic devices 600b may also be connected with photovoltaic devices prepared from other methods in real life applications.

Referring to FIG. 10, there is shown a top view of one or more shapes of the first substrate 502 used for manufacturing the organic photovoltaic device 600a or the organic photovoltaic device 600b. The first substrate 502 can be of any shape as long as the size of the first substrate 502 is less than 900 square centimeters. The first substrate 502 can be a circular substrate 1000a, a triangular substrate 1000b, or a hexagonal substrate 1000c. Although, the shape of the first substrate 502 is shown as circular, triangular or hexagonal in FIG. 10, it will be readily apparent to those skilled in the art that the invention can be practiced with the first substrate 502 of a shape that can be, but is not limited to, polygonal, annular or elliptical. The organic photovoltaic device obtained from one or more substrates 1000a, 1000b, 1000c can be combined in series or parallel to form a photovoltaic device of any desired shape. For example, a hexagonal shaped photovoltaic device can be obtained by combining square and triangular shaped photovoltaic devices. The shape of the photovoltaic device obtained from combining the photovoltaic devices can be, but is not limited to, square, rectangular, circular, triangular, hexagonal, polygonal, annular or elliptical.

Various embodiments, as described above, provide a method for manufacturing an organic photovoltaic device, which has several advantages. One of the several advantages of some embodiments of this method is that a quality of the organic photovoltaic devices manufactured using this method is good, since, manufacturing processes used for deposition of various layers are conventional and standardized processes that have been tried and tested to be suitable for the pre-defined size of substrates to which the invention is applicable, i.e., the small form factor. This implies that a uniformity of deposited layers is substantially acceptable as well as the deposited layers have no or lesser defects like, pinholes and non-homogeneity of the layer. Further, since the substrates and organic photovoltaic device in accordance with the present invention are smaller in size, they can be easily handled and processed. This saves significant time and makes the process efficient.

Further, in the manufacturing method disclosed in the present invention there is no cutting or slicing of the substrate after deposition of layers leading to a substrate sized organic photovoltaic device. Since no cutting or slicing of the substrate is involved after deposition of layers there is no loss of material used in the deposited layers due to cutting or slicing and devices can be mass manufactured with high yield. This lowers the manufacturing cost of the device and makes the method efficient.

The method according to the present invention is used for manufacturing an organic photovoltaic device using small form factor substrates. The small sized devices manufactured from the small form factor substrate can be combined to form larger devices of any desired shape without loss of product due to cutting or slicing of the substrate. The shape of the larger device can be, but is not limited to, square, rectangular, circular, triangular, hexagonal, polygonal, annular or elliptical. Thus the method of manufacture as disclosed in the present invention provides devices of customizable shapes without loss of product.

A setup cost or capital cost of a manufacturing facility for implementing the method disclosed in the present invention is significantly lesser as compared to the existing methods. All the processes used in the present invention are conventional and standardized processes, therefore, the corresponding equipments are also standard and conventional and hence less expensive. Additionally, since the substrates and the organic photovoltaic device in accordance with the method of the present invention are of small form factor, the manufacturing equipment required is also correspondingly smaller in size, therefore, less expensive.

The method according to the present invention has another advantage that it enables mass production with high-throughput and yield since all the layers can be deposited by using high-throughput processes.

As described above, the capital cost for the manufacturing facility is less. Therefore, a cost of the organic photovoltaic device is also less. At the same time, an efficiency and quality of the organic photovoltaic device is better. Therefore, another advantage of implementing the method according to the present invention is significantly low cost per unit of power produced. While the invention has been disclosed in connection with the preferred embodiments shown and described in detail, various modifications and improvements thereon will become readily apparent to those ordinarily skilled in the art. Accordingly, the spirit and scope of the present invention is not to be limited by the foregoing examples, but is to be understood in the broadest sense allowable by law.

All documents referenced herein are hereby incorporated by reference.

What is claimed is:

1. A method of manufacturing an organic photovoltaic device of a pre-defined shape and size, the method comprising:
providing a first substrate of said pre-defined shape and size, wherein said pre-defined size is less than 900 square centimeters;
depositing organic photoactive layer on said first substrate;
depositing electrically conducting layer on said organic photoactive layer;
scribing of said electrically conducting layer and said organic photoactive layer from said first substrate, wherein said scribing forms zones of said electrically conducting layer and said organic photoactive layer on said first substrate, whereby forming an active substrate;
providing a second substrate of said pre-defined shape and size;
depositing a gas-absorbent layer on said second substrate, whereby forming an inactive substrate; and
encapsulating said active substrate with said inactive substrate to form said organic photovoltaic device of said pre-defined shape and size, whereby not cutting said first substrate after deposition of said organic photoactive layer.

2. The method as recited in claim 1, wherein said first substrate comprises a glass substrate and at least one of a transparent conducting coating or an electrically conducting grid.

3. The method as recited in claim 1, wherein said method is conventionally optimized for an optimum production rate with an optimum tact time.

4. The method as recited in claim 1 further comprising, depositing a hole-transport layer on said first substrate prior to depositing of said organic photoactive layer, wherein said hole-transport layer being deposited using a high-throughput process, further wherein said high-throughput process for depositing said hole-transport layer being suitable for said pre-defined size.

5. The method as recited in claim 4, wherein said high-throughput process for depositing said hole-transport layer comprises dip coating, spin coating, doctor blade processing, spray coating, screen printing, sputtering, electroforming, evaporation, a batch deposition-processing and an in-line process.

6. The method as recited in claim 1, wherein said high-throughput process for depositing said electrically conducting layer comprises dip coating, spin coating, doctor blade processing, spray coating, screen printing, sputtering, electroforming, evaporation, a batch deposition-processing and an in-line process.

7. The method as recited in claim 1, wherein said high-throughput process for depositing said gas-absorbent layer comprises dip coating, spin coating, doctor blade processing, spray coating, screen printing, sputtering, electroforming, evaporation and an in-line process.

8. The method as recited in claim 1, wherein said high-throughput process for depositing said gas-absorbent layer comprises either a batch deposition-processing or an in-line process.

9. A method of manufacturing an organic photovoltaic device, the organic photovoltaic device having a pre-defined surface area, the method comprising:
providing a first substrate, wherein a surface area of said first substrate is substantially equal to said pre-defined surface area, further wherein said pre-defined surface area is not greater than 900 square centimetres;
depositing one or more organic or inorganic material layers on said first substrate, wherein each of said one or more organic material layers is deposited by using either a batch deposition-process or an in-line process;
first high-throughput deposition-processing on said one or more organic material layers, wherein said first high-throughput deposition-processing being substantially suitable for said pre-defined surface area;
providing a second substrate, wherein a surface area of said second substrate is substantially equal to and not greater than said pre-defined surface area;
second high-throughput deposition-processing on said second substrate, wherein said second high-throughput deposition-processing being substantially suitable for said pre-defined surface area; and
encapsulating or bonding said first substrate with said second substrate to form said organic photovoltaic device, wherein said organic photovoltaic device is a product itself, further wherein said device does not require a subsequent cutting process to achieve said pre-defined size of said organic photovoltaic device.

10. The method as recited in claim 9, wherein depositing said one or more organic material layers on said first substrate comprises depositing a first organic photoactive layer on said first substrate.

11. The method as recited in claim 10, wherein depositing said one or more organic material layers on said first substrate further comprises depositing at least one of a hole-transport layer, an electrically conducting layer and a second organic photoactive layer.

12. The method as recited in claim 9, wherein said first substrate comprises a glass substrate and at least one of a transparent conducting coating and a conducting grid.

13. The method as recited in claim 9, wherein said method is conventionally optimized for an optimum production rate with an optimum tact time.

14. The method as recited in claim 9, wherein said first high-throughput deposition-processing on said one or more organic material layers comprises high-throughput depositing of an electrically conducting layer.

15. The method as recited in claim 9, wherein said first high-throughput deposition-processing comprises at least one of dip coating, spin coating, doctor blade processing, spray coating, screen printing, sputtering, electroforming, evaporation and an in-line process.

16. The method as recited in claim 9, wherein said second high-throughput deposition-processing comprises at least one of dip coating, spin coating, doctor blade processing, spray coating, screen printing, sputtering, electroforming, evaporation and an in-line process.

17. The method as recited in claim 9, wherein said first high-throughput deposition-processing comprises either a batch deposition-processing or an in-line processing.

18. The method as recited in claim 9, wherein said second high-throughput deposition-processing comprises either a batch deposition-processing or an in-line processing.

19. The method as recited in claim 9 further comprising connecting one or more organic photovoltaic devices in at least one of parallel and series connections, whereby optimizing an electrical output from said one or more organic photovoltaic devices.

20. A method of manufacturing an organic photovoltaic device, the organic photovoltaic device having a pre-defined surface area, the method comprising:
providing a first substrate, wherein a surface area of said first substrate is substantially equal to said pre-defined surface area, further wherein said pre-defined surface area is not greater than 900 square centimeters;
high-throughput depositing of a hole-transport layer on said first substrate, wherein said high-throughput depositing of said hole-transport layer being suitable for said pre-defined surface area;
depositing a first organic photoactive layer on said hole-transport layer, wherein said first organic photoactive layer is deposited by using either a batch deposition-process or an in-line process;
optional high-throughput depositing of a first electrically conducting layer on said first organic photoactive layer, wherein said optional high-throughput depositing of said first electrically conducting layer being suitable for said pre-defined surface area;
optionally depositing a second organic photoactive layer on said first electrically conducting layer, wherein said second organic photoactive layer is deposited by using either a batch deposition-process or an in-line process;
high-throughput scribing of said second organic photoactive layer, said first electrically conducting layer, said first organic photoactive layer and said hole-transport layer from the first substrate;
high-throughput depositing of a second electrically conducting layer on said scribed second organic photoactive layer, wherein said high-throughput depositing of said second electrically conducting layer being suitable for said pre-defined surface area;
high-throughput scribing of said second electrically conducting layer from said first substrate, whereby forming an active substrate;
providing a second substrate, wherein a surface area of said second substrate is substantially equal to and not greater than said pre-defined surface area;
high-throughput depositing of a gas-absorbent layer on said second substrate, whereby forming an inactive substrate, wherein said high-throughput depositing of said gas-absorbent layer being suitable for said pre-defined surface area; and
encapsulating or bonding said active substrate with said inactive substrate to form said organic photovoltaic device, wherein said organic photovoltaic device is a product itself, further wherein said device does not require a subsequent cutting process to achieve said pre-defined size of said organic photovoltaic device.
